(19) United States
(12) Patent Application Publication
(10) Pub. No.: US 2026/0362870 A1
(43) Pub. Date: Nov. 12, 2026

(54) MULTI-CARTRIDGE BUILD

(71) Applicant: VueReal Inc., Waterloo (CA)

(72) Inventors: Gholamreza CHAJI, Kitchener (CA); Hossein Zamani SIBONI, Waterloo (CA); Dana Saud Yousef AYYASH, Waterloo (CA); Danish BAIG, Waterloo (CA)

(73) Assignee: VueReal Inc., Waterloo, ON (CA)

(21) Appl. No.: 19/133,019

(22) PCT Filed: Dec. 6, 2023
(86) PCT No.: PCT/IB2023/062334

§ 371 Date: May 27, 2025

Related U.S. Application Data
(60) Provisional application No. 63/386,262, filed on Dec. 6, 2022.
(60) Provisional application No. 63/514,951, filed on Jul. 21, 2023.

(51) Int. Cl. H10H 29/02

(52) U.S. Cl. CPC H10H 29/02

(57) ABSTRACT

The present invention discloses various methods of building multi-cartridges. In particular, methods using Adhesive-based Direct Build, Adhesive-based Simultaneous Build, Mechanical Direct Build, Modular Anchor Direct Build and Modular Anchor Direct Build with Color Conversion, and transfer of microdevices from a cartridge to a release layer located on a template are discussed. Further, use of intermediate substrate, alignment, using pockets as template substrate, using pockets as carrier Substrate, method to improve template are also discussed.

### CROSS-REFERENCE TO RELATED APPLICATIONS

This application claims priority to and the benefit of U.S. Provisional Patent Application No. 63/386,262, filed Dec. 6, 2022, and U.S. Provisional Patent Application No. 63/514,951, filed, Jul. 21, 2023, each of which is hereby incorporated by reference here in its entirety.

### FIELD OF THE INVENTION

The present disclosure relates to different mechanisms of building Multi-cartridges.

### SUMMARY

The present invention relates to a method to build a multi-cartridge, using an adhesive based direct build, the method comprising, patterning alignment marks on a highly planar substrate and dice the planar substrate into several template pieces, applying an adhesive to a template, picking up a cartridge face-up with a bond head, aligning a back of the cartridge and a top of the template using the alignment marks or cartridge corner present on both surfaces, bonding the cartridge to the template, and repeating the last three steps until all desired cartridge locations on the template are filled and a multi-cartridge build is complete.

The present invention also relates to a method to build a multi-cartridge, using a mechanical direct build, the method comprising, patterning and etching precision recesses into a ceramic template, completed in two pattern and etch steps, one for recess walls, one for the vacuum holes, placing stainless steel compressions springs or a V-shaped torsion spring into the recesses, and loading cartridges face-up into each recess manually or using a jig, such that each cartridge is oriented the same as the others and tensioned against the recess walls.

The present invention also relates to a method to build a multi-cartridge, using an adhesive based simultaneous build, the method comprising, patterning alignment marks on a highly planar substrate, patterning adhesive bumps on a highly planar temporary bonding substrate to selectively transferring microLED's from a cartridge, holding the temporary bonding substrate to a tool stage, picking-up the cartridge face-down using a bond-head, aligning a top of the cartridge and the adhesive bumps on the substrate using fiducials or other features (ex. cartridge corner) present on both surfaces, bonding the cartridge to the substrate such; and repeating last three steps until all desired cartridge locations on the substrate are filled.

The present invention also relates to a method to build a multi-cartridge, using a modular anchor direct build, the method comprising, patterning a sacrificial layer on a template with openings for anchor points in a structural layer, having alignment marks to allow for an integration in pick-and-place tools, depositing a structural layer which is anchored to the template substrate, then patterning it to allow for a tuned mechanical breakage during a microdevice printing, dicing the template into several template pieces, patterning adhesive bumps on a top of the structural layer to transfer all microdevices from a cartridge to the template, vacuuming a template piece to the pick-and-place tool stage, picking-up the cartridge face-down using a vacuum bond-head, aligning a top of the cartridge and the adhesive bumps on the template using fiducials or cartridge corners present on both surfaces, bonding the cartridge to the template such that only the bond-head is applying heat in order to prevent an adhesive curing of the whole template, and repeating last three steps until all desired cartridge locations on the template are filled, creating a multi-cartridge.

The present invention also relates to a method to build a multi-cartridge the method comprising, forming a release layer on a template with opening for anchor points in a diaphragm layer; forming fiducials to improve the alignment accuracy during microdevice integration to the template; depositing a diaphragm layer which is anchored to the template substrate, then patterning it to individual diaphragms associated to each microdevice allowing separating individual microdevices from the template during the transfer process, wherein the template substrate includes more than one template piece and to be separated into several template pieces by a mechanical dicing or a laser cutting, patterning bonding pads/bumps on a top of the diaphragm layer to transfer all microdevices from the cartridge to the template, aligning a donor substrate with secured microdevices facing toward the template bonding pads with a location in the template wherein the devices are secured to the donor substrate with different means such as adhesive, or mechanical release layers., wherein further the microdevices of the donor are bonded to the template, and repeating the last three steps until all desired locations on the template are filled, creating a multi-cartridge.

The present invention also relates to a method to build a multi-cartridge, using an adhesive based direct build with color conversion, the method comprising, forming a release layer on the template with opening for anchor points in a diaphragm layer, forming fiducials to improve an alignment accuracy during microdevice integration to the template, depositing a diaphragm layer which is anchored to the template substrate, then patterning it to an individual diaphragm associated to each microdevice to allow separating individual microdevices from the template during the transfer process, wherein the template substrate includes more than one template piece, integrating functional layers on a top of diaphragm wherein the functional layers include one or more of the one of passivation layers, color conversion layer, and color filter, patterning bonding pads on top of the diaphragm structural layer to transfer microdevices from the donor substrate to the template, integrating the microdevices into the bonding pads of the template by aligning a donor substrate with the area of the template, bonding a selected set of microdevices into the bonding pads, and repeating the process till all selected areas of templates are populated with microdevices.

The present invention also relates to a method to load micro devices with cartridges, the method comprising, loading a cartridge with the microdevices from a donor substrate where the process includes forming release layers on a substrate, forming a diaphragm on the release layer wherein the diaphragm is connected to the substrate through an opening in the release layer, and bonding microdevices to the diaphragm through an adhesive or a bonding layer.

### BRIEF DESCRIPTION OF THE DRAWINGS

In this description, the term “microLED” and “microdevice” are used interchangeably.

The foregoing and other advantages of the disclosure will become apparent upon reading the following detailed description and upon reference to the drawings:

FIG. 1 shows the process flow for inspection and metrology of a set of cartridges to determine their binning categories.

FIG. 2 describes how an offset (low precision) in the multi-cartridge assembly process can result in poorly aligned microLED.

FIG. 3 shows a case of an Adhesive-based Direct Build to build a multi-cartridge.

FIGS. 4A and 4B show a case of an Adhesive-based Simultaneous Build to build multi-cartridges.

FIG. 5 shows an optical alignment process of the Adhesive-based Simultaneous Build.

FIG. 6 shows a case of Adhesive-based Build with Spacer Beads.

FIG. 7 shows a case of Mechanical Direct Build to build multi-cartridges.

FIGS. 8A, 8B and 8C show an optoelectronic system with the pads on one surface.

FIG. 9 shows an intermediate substrate that comprises alignment marks and a temporary adhesive layer.

FIG. 10 shows an intermediate substrate that comprises grooves.

FIG. 11 shows placing the cartridge in a pocket and use vibration for accurate placement.

FIG. 12 shows that a tool can be used that has vacuum holes aligned with the cartridges in the carrier substrate.

FIGS. 13A, 13B and 13C show a case of Mechanical Direct Build to build multi-cartridges.

FIG. 14 shows modular anchor direct build with color conversion layer.

FIGS. 15, 16 and 17 show that the implementation is identical to implementation Modular Anchor Direct Build, but a color conversion layer is embedded into the structural layer.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

Selective transfer and binning of high quality LED cartridges are extremely desirable features for microLED display manufacturers. More selective binning processes require scale down of dice dimensions, which also scales down production rate per die when populating a microLED display.

The multi-cartridge is an invention consisting of a highly planar template with several microLED cartridges, which have been binned through an inspection process to ensure high quality, fixed to it. Binning involves distributing cartridges into categories dependent on defect presence (such as particles or damaged microstructures) and optical properties (such as emission wavelength), for ultimate use towards an appropriate final application. These categories can be determined through an inspection process that may involve optical image recognition and evaluation by several thin film or semiconductor metrology tools.

The cartridges are fixed to the template with high accuracy and precision to ensure misalignment of microLED's during the printing process is below a desired margin, depending on microLED size and backplane contact size. Since microLED contacts must align with the backplane contacts within a desired margin to ensure proper device performance, the precision of the multi-cartridge assembly process should result in cartridges fixed in 2D-space below the desired margin. Fiducials (or alignment marks) on both the cartridges and template will allow for active alignment, depending on the assembly process, and for measurements to verify accurate alignment after assembly. Transfer printing with the multi-cartridge will multiply the production rate of the display population process by however many cartridges can be successfully attached to the template.

This invention addresses the following aspects, highly accurate and precise fixing of the cartridges to the template (or vice-versa) to enable greater display production rate and limit repair after display population and a form factor change of several binned dice from a wafer/s to any arrangement on the template, customizing the solution to the needs of the final microLED display.

### Methods of Building Multi Cartridges

There are multiple methods of building multi-cartridges.

### Binning and Inspection

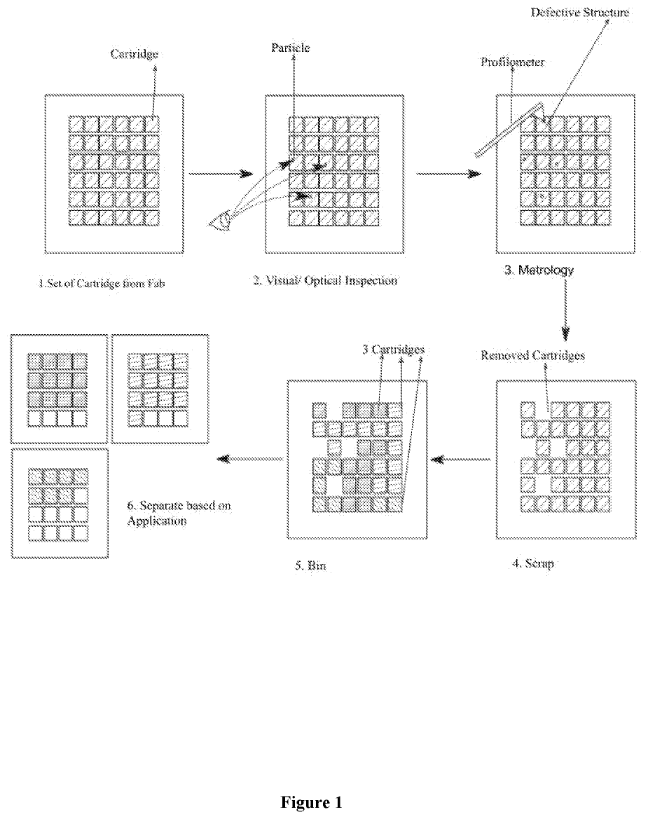

FIG. 1 shows the process flow for inspection and metrology of a set of cartridges to determine their binning categories. Cartridges in a holder/waffle that do not fall within the specification of any category, such as those having significant particle count or device defects can be scrapped. The remainder are binned and separated to be used towards the desired applications. The process starts from a set of cartridges from the fabrication step. Then there is a visual/optical inspection. Then a metrology step takes place where cartridges are profiled by a profilometer (just as an example) and defective structures are scrapped. After that remaining cartridges are binned according to their various parameters or characteristics.

### Desired Margin

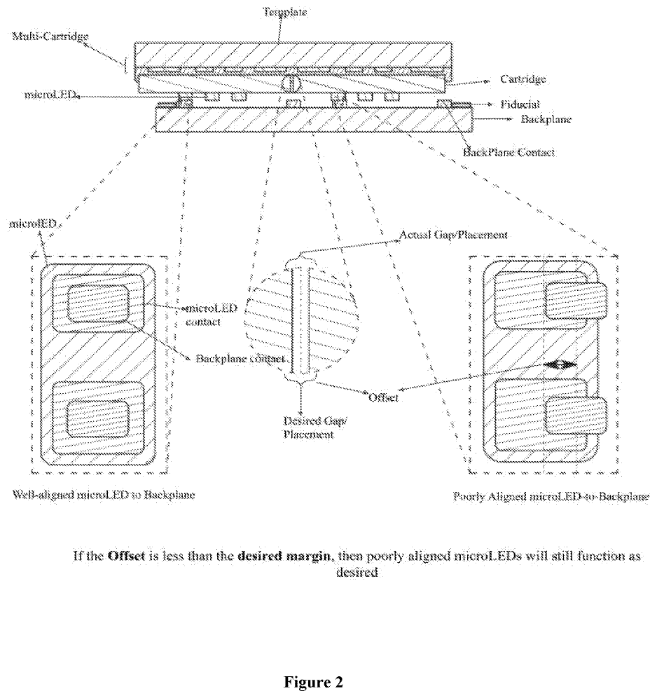

FIG. 2 describes how an offset (low precision) in the multi-cartridge assembly process can result in poorly aligned microLED's during the transfer process to a backplane. In order for the multi-cartridge assembly to be successful, the offset between cartridges must be below a desired margin to ensure device functionality after transfer.

### Adhesive-Based Direct Build

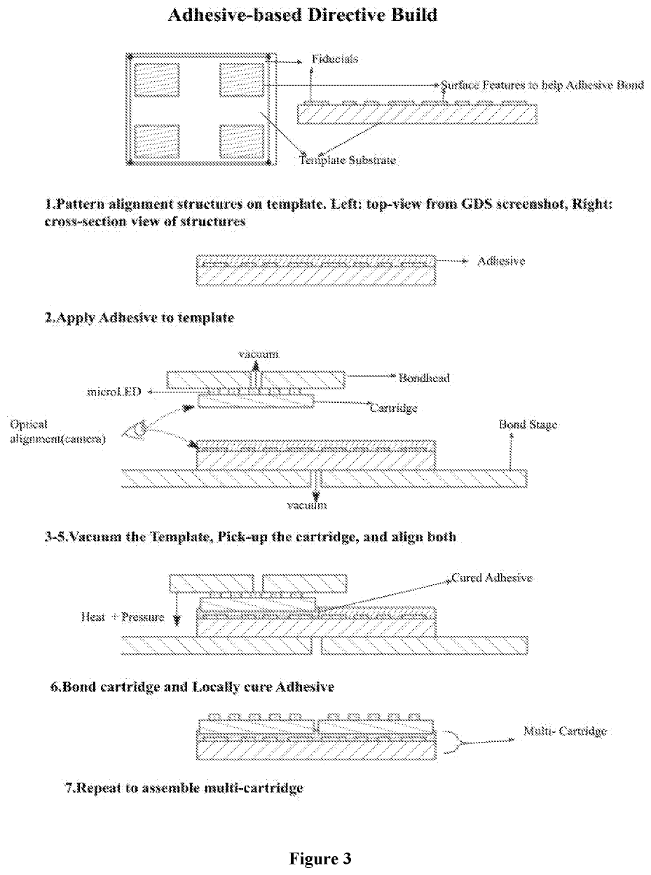

FIG. 3 shows a case of an Adhesive-based Direct Build to build a multi-cartridge. This implementation involves an active alignment of the backside of the cartridges to the top surface of the template (receiver substrate). The template is coated with an adhesive to fix (bond) the cartridges to its surface once placed. Misalignment in this process is derived primarily from the placement accuracy of the pick-and-place die bonding tool used.

A typical process for Adhesive-based Direct Build may be as follows:
1 Pattern alignment marks on a highly planar substrate and dice the substrate into several template pieces.
2. Apply a thermally cured adhesive to the template via spinning, spraying, dipping, or rod coating.
3. Vacuum the template to the pick-and-place tool stage.
4. Pick up the cartridge face-up using a vacuum bond-head.
5. Align the back of the cartridge and the top of the template using fiducials (alignment marks) or other features (ex. cartridge corner) present on both surfaces.
6. Bond the cartridge to the template such that only the bond-head is applying heat in order to prevent adhesive curing of the whole template.
7. Repeat steps 4-6 until all desired cartridge locations on the template are filled and the multi-cartridge build is completed.

Some of the likely advantages of Adhesive-based Direct Build approach are, low misalignment that can be actively corrected for by the bonding tools.

On the flip side the disadvantages of Adhesive-based Direct Build may have: Fiducial or feature detection of active area via optical cameras may be challenging through the thickness of the cartridge (distortions, refraction, etc.), corner detection of the backside of the cartridge may suffice, but needs to be tested. Sensitive features on the microLED surface may be damaged by direct contact with the bond-head, can avoid the keep-out-zone by including a custom recess in the bond-head, protective coatings can be added to the cartridge, but solvents or corrosives needed to remove that protection must be compatible with the template adhesive. Temperature difference between the bond-head and tool stage may result in additional stress or misalignment due to CTE mismatch and can be counteracted by completely cooling the pieces during bonding, but this increases assembly time.

### Adhesive-Based Simultaneous Build

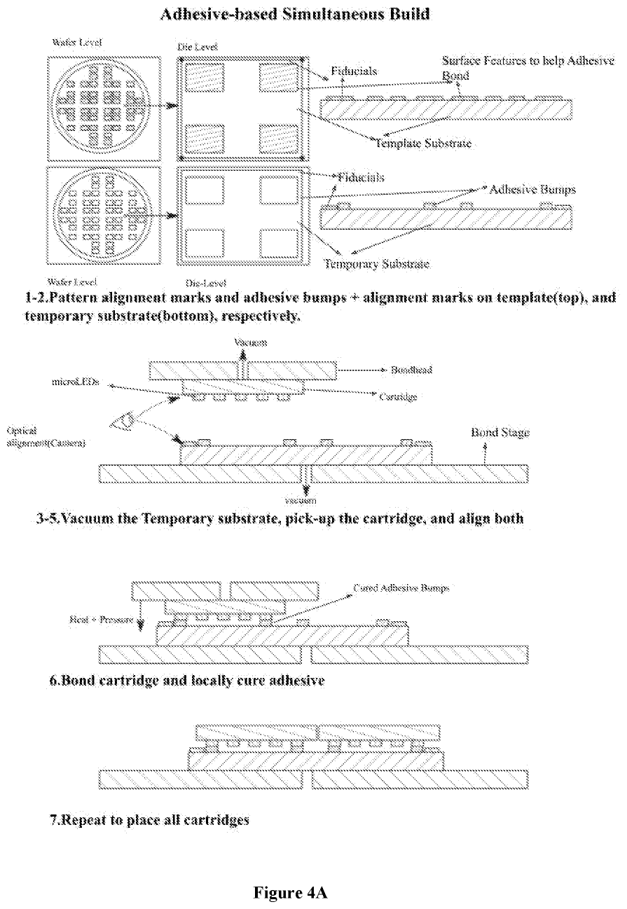

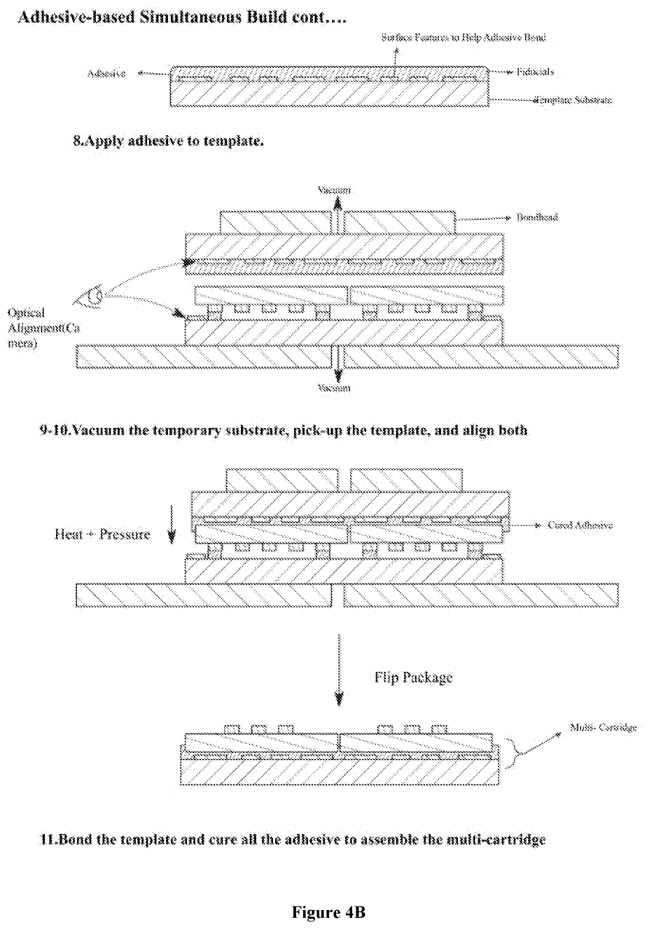

FIGS. 4A and 4B show a case of an Adhesive-based Simultaneous Build to build multi-cartridges. This implementation involves active alignment and placement of the top surfaces of the cartridges to a temporary bonding substrate. Once all cartridges are placed in their desired locations on the substrate, a template coated with an adhesive is aligned and bonded to the backside of all cartridges simultaneously. Misalignment in this process is derived primarily from the placement accuracy of the pick-and-place die bonding tool used, and is a sum of misalignment introduced during both the cartridge placement step and the template bonding step.

A typical process for Adhesive-based Simultaneous Build would likely go as follows:
1. Pattern alignment marks on a highly planar substrate and dice the substrate into several template pieces.
2. Pattern adhesive bumps on a highly planar temporary bonding substrate to selectively transfer some, but not all, microLED's from the cartridge.
3. Vacuum the temporary bonding substrate to the pick-and-place tool stage.
4. Pick-up the cartridge face-down using a vacuum bond-head.
5. Align the top of the cartridge and the adhesive bumps on the substrate using fiducials or other features (ex. cartridge corner) present on both surfaces.
6. Bond the cartridge to the substrate such that only the bond-head is applying heat in order to prevent adhesive curing of the whole substrate.
7. Repeat steps 4-6 until all desired cartridge locations on the substrate are filled.
8. Apply a thermally cured adhesive to the template via spinning, spraying, dipping, or rod coating.
9. Pick-up the template face-down using a vacuum bond-head.
10. Align the top of the template and the temporary substrate using fiducials present on both surfaces.
11. Bond the template to the backside of all cartridges simultaneously and lift-off from the tool stage, transferring some microLED's onto the adhesive bumps, to complete the multi-cartridge.

This process has many advantages such as, avoiding contact with sensitive active area of the cartridge, all cartridges will have the same misalignment with respect to the template, so this misalignment is canceled out-leaving only misalignment from bonding the cartridges to the temporary substrate and reduced CTE mismatch by assembling the multi-cartridge while the bond-head and tool stage temperatures are identical. One flip side is that additional steps may be required compared to the direct build.

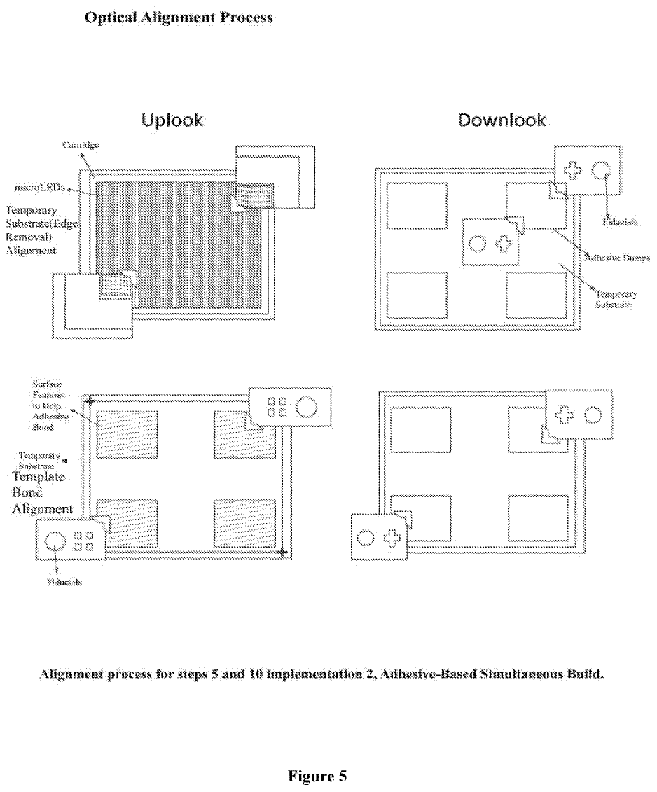

FIG. 5 shows an optical alignment process of the Adhesive-based Simultaneous Build.

Adhesive-Based Build with Spacer Beads

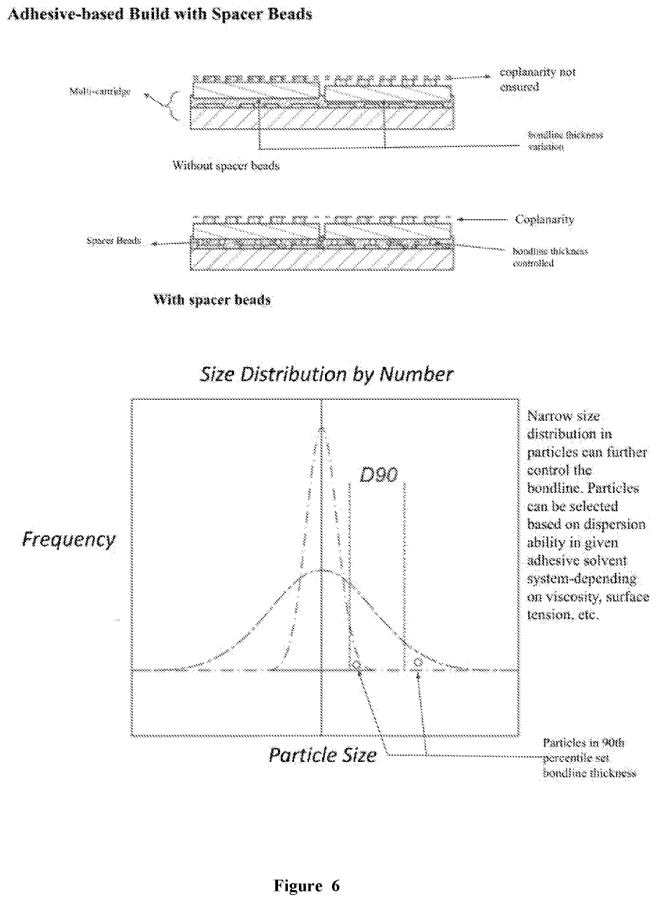

FIG. 6 shows a case of Adhesive-based Build with Spacer Beads. To augment the x- and y-axis alignment achieved in the implementations described above, the z-axis depth can also be controlled by maintaining a consistent bond-line thickness across the template adhesive at all cartridge locations. Introducing spacer beads, comprising of size-controlled spherical glass or ceramic particles, into the adhesive (adhesive has beads before application) can allow for the bond-line thickness of all cartridges fixed to the template to remain uniform. The thickness may be set by the largest beads present underneath each cartridge at the time of bonding. This addition will ensure all points on the multi-cartridge will have uniform touchdown during microLED display population, reducing defects.

### Mechanical Direct Build

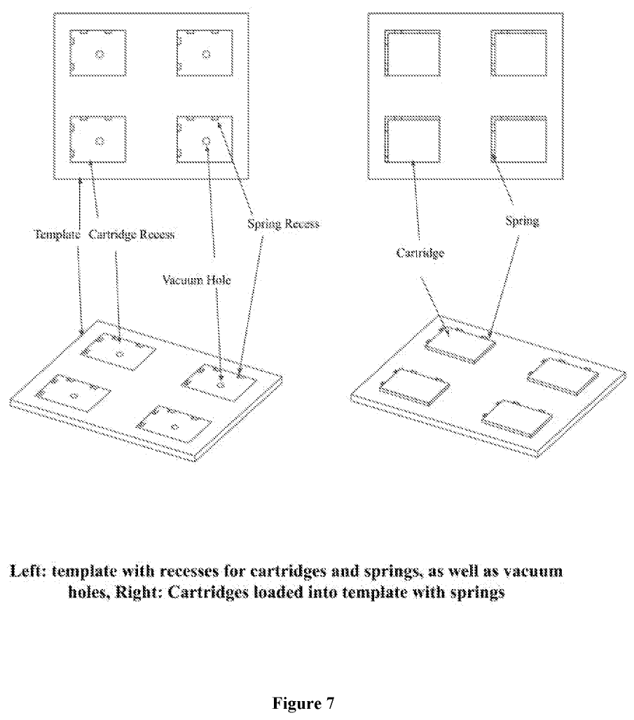

FIG. 7 shows a case of Mechanical Direct Build to build multi-cartridges. In the mechanical direct build, the template would serve as a temporary substrate as the cartridges are not permanently bonded to it. This implementation does not involve an active alignment and relies on loading of cartridges into pre-defined recesses on the template (Temporary substrate). To fix the cartridges in place against the walls of the recesses, low-profile springs can be used to tension the cartridges. Vacuum holes located in the bottom face of the recesses can further reinforce the cartridges by allowing the bond-head's vacuum to fix them in place. Misalignment in this process is derived primarily from the precise dimensions and wall roughness of each cartridge (dicing dependent) and the wall roughness of the template recesses.

A typical process for this build would likely go as follows:
1. Pattern and etch precision recesses into a ceramic template, completed in two pattern and etch steps (one for the recess walls, one for the vacuum holes). Here deep recesses can be micromachined in silicon using the Bosch process, which will have negligible wall roughness (10s of nm RMS) (This is the most common way, but there are many other ways to micromachine this recess) (deep recesses can be micromachined in silicon, ceramic or glass).
2. Place stainless steel compressions springs or V-shaped torsion spring into the recesses.
3. Load the cartridges face-up into each recess manually or using a jig, such that each cartridge is oriented the same as the others and tensioned against the recess walls.

Some of the advantages of this process comprise of: Assembly does not require precision tools, The template can be reused once all cartridges are consumed. No polymer materials allows for good chemical resistance, enabling more flexibility in process sequence (can still wet etch or clean cartridges after loading). In this case Elgiloy springs are a good candidate.

On the flip side the disadvantages are likely to be: Dicing of sapphire (typical microLED substrates) is uncommon, and can be more variable than glass or silicon, making this implementation unviable for certain substrates due to non-uniformity. Finding appropriate springs with desired dimensions may be challenging. To overcome this one can source custom micro springs made of chemically resistive alloys or one can use polymeric springs made via two-photon lithography.

### Modular Anchor Direct Build

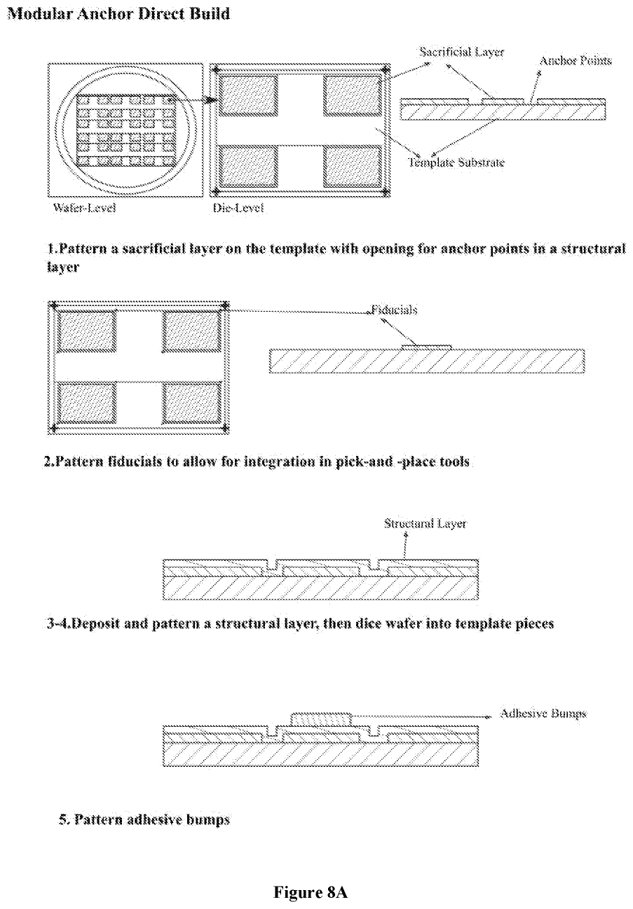

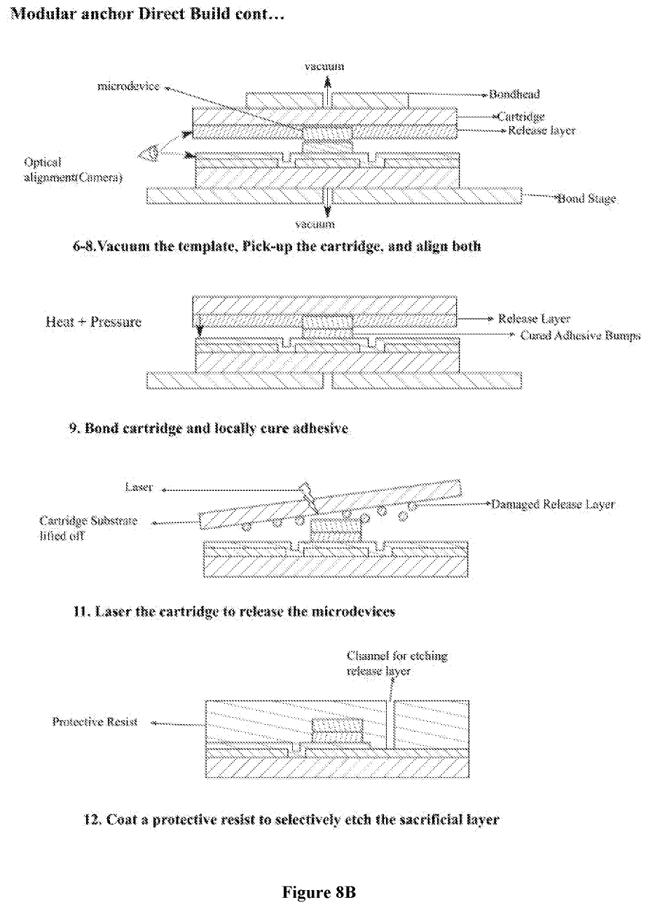

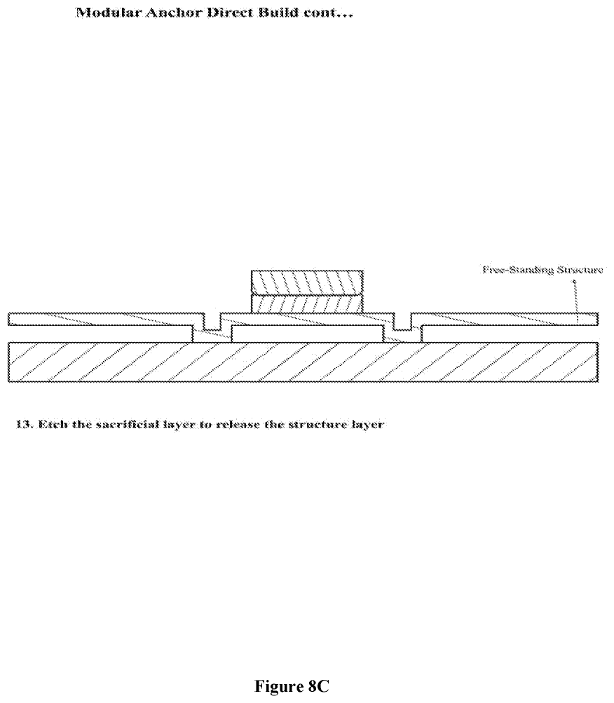

FIGS. 8A, 8B and 8C, show a case of Modular Anchor Direct Build to build multi-cartridges. This implementation involves transfer of microdevices from a cartridge to a release layer located on the template. To facilitate the transfer, a laser-activated release layer is present on the cartridges initially. The backside of the microdevices are bonded to the template's release layer via an adhesive, then the microdevices are released from the cartridge using laser excitation. In this scenario the cartridge would act as a donor substrate while the template is a receiver substrate.

A typical process for Modular Anchor Direct Build comprises of:
1. Pattern a sacrificial layer on the template with opening for anchor points in a structural layer.
2. Alignment marks allow for an integration in pick-and-place tools.
3. Deposit a structural layer which is anchored to the template substrate, then pattern it to allow for tuned mechanical breakage during microdevice printing.
4. Dice the template into several template pieces.
5. Pattern adhesive bumps on top of the structural layer to transfer all microdevices from the cartridge to the template.
6 Vacuum the template piece to the pick-and-place tool stage.
7. Pick-up the cartridge face-down using a vacuum bond-head.
8. Align the top of the cartridge and the adhesive bumps on the template using fiducials or other features (ex. cartridge corner) present on both surfaces.
9. Bond the cartridge to the template such that only the bond-head is applying heat in order to prevent adhesive curing of the whole template.
10. Repeat steps 4-6 until all desired cartridge locations on the template are filled, creating a multi-cartridge.
11. Laser the cartridges to release the microdevices from the cartridge substrate and transfer onto the template.
12. Coat and pattern protective resist on the template if required for protection of the device during etching of the sacrificial layer.
13. Etch the sacrificial layer to release free-standing structures which can be used to print microdevices from the multi-cartridge.

One method to improve the template development, applicable to the methods described above, is to secure the cartridges (or donor substrates) in an intermediate substrate. Then the template is used to bond, hold or adhere to all cartridges at once.

FIG. 9 shows an intermediate substrate that comprises alignment marks and a temporary adhesive layer. The adhesive layer does not require patterning in this structure although one may pattern it for better alignment.

In one method, alignment marks are formed on the intermediate substrate and an adhesive layer is added to the substrate. Cartridges are aligned with a location in the carrier substrate and bonded to the carrier substrate (microdevices facing the carrier substrate). After all cartridges are bonded to the carrier substrate, a template is used to bond to all the cartridge substrates. The template has a bonding layer that will adhere to the cartridge substrate. The bonding layer can be patterned adhesive, metal, or other type of polymer. After bonding, the cartridges are de-bonded from the carrier substrate.

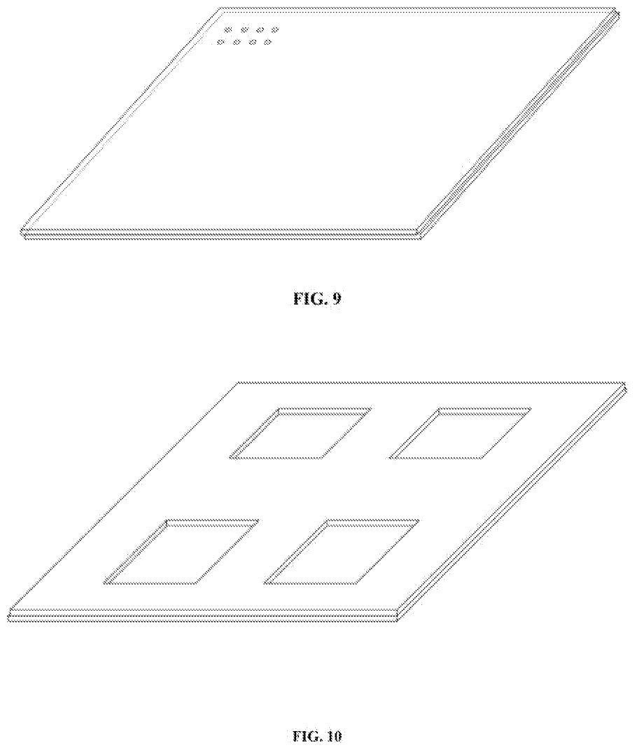

FIG. 10, applicable to the methods described above, shows an intermediate substrate that comprises grooves. These grooves match one structure in the cartridge (for example the base frame holding the microdevices) or the cartridge substrate. The cartridge is put in these grooves facing down (microdevices are facing the intermediate carrier substrate). After cartridges are in place, vibration or air or liquid can be used to place the cartridges in the perfect place. After all cartridges are in perfect place, a template is used to bond to all the cartridge substrates. The template has a bonding layer that will adhere to the cartridge substrate. The bonding layer can be patterned adhesive, metal, or other type of polymer. After bonding, the cartridges are de-bonded from the carrier substrate.

### Using Pockets as Template Substrate for Above Methods

Preparing a template substrate: Etching pockets in the substrate the same size as cartridge substrate. Alignment marks are needed. There needs to be an attraction force to hold the cartridges in place (selective vacuum, ESD, or adhesive can be used). The structure can be used directly to populate the display.

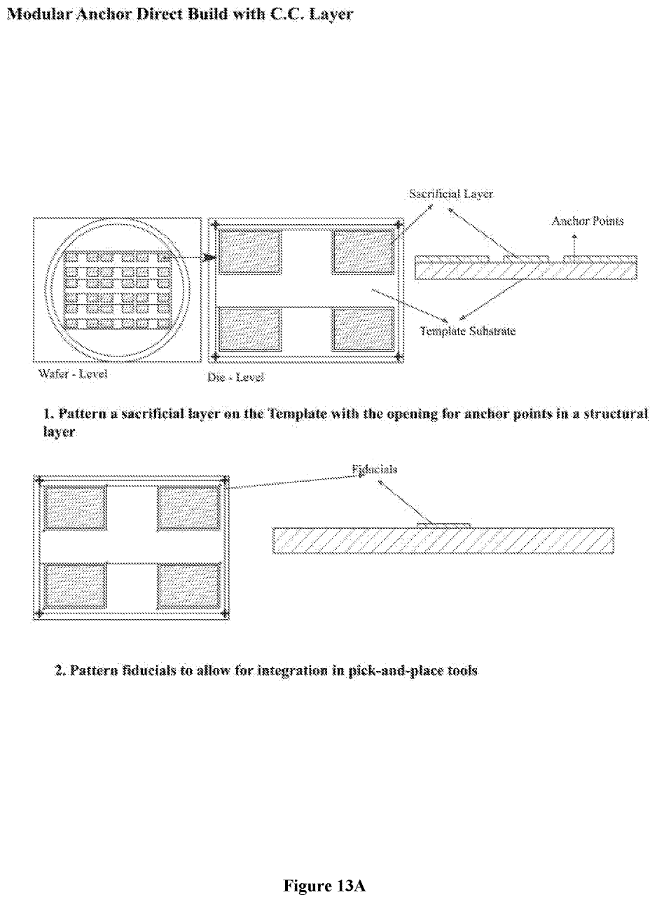

FIG. 12 shows that a tool can be used that has vacuum holes aligned with the cartridges in the carrier substrate. This way we can pick the cartridges without a second adhesive or bonding.

### Using Pockets as Carrier Substrate for Above Methods

Preparing a carrier substrate, etching pockets in the substrate the same size as active cartridge active layer We need alignment marks (selective vacuum may be used to enhance the process)

Placing the cartridges on top of the structures bonding a template substrate to the setup (it can be either sapphire with SU8 or sapphire with Kapton tape at the bonding temperature).

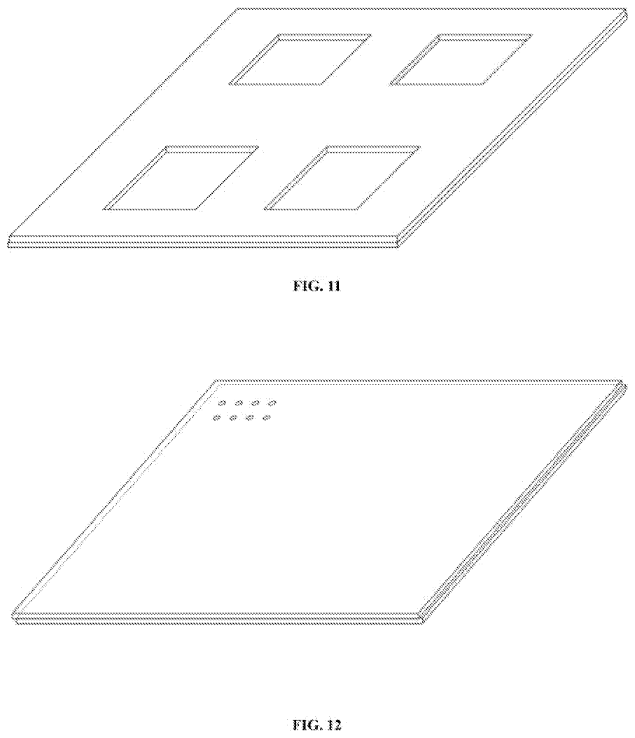

FIG. 11 shows that one can place the cartridge in a pocket and use vibration for accurate placement (this will be faster).

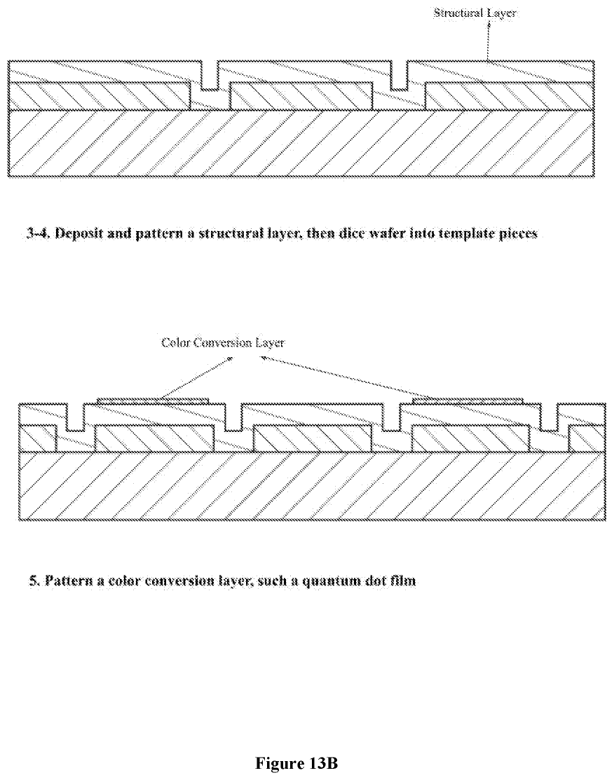

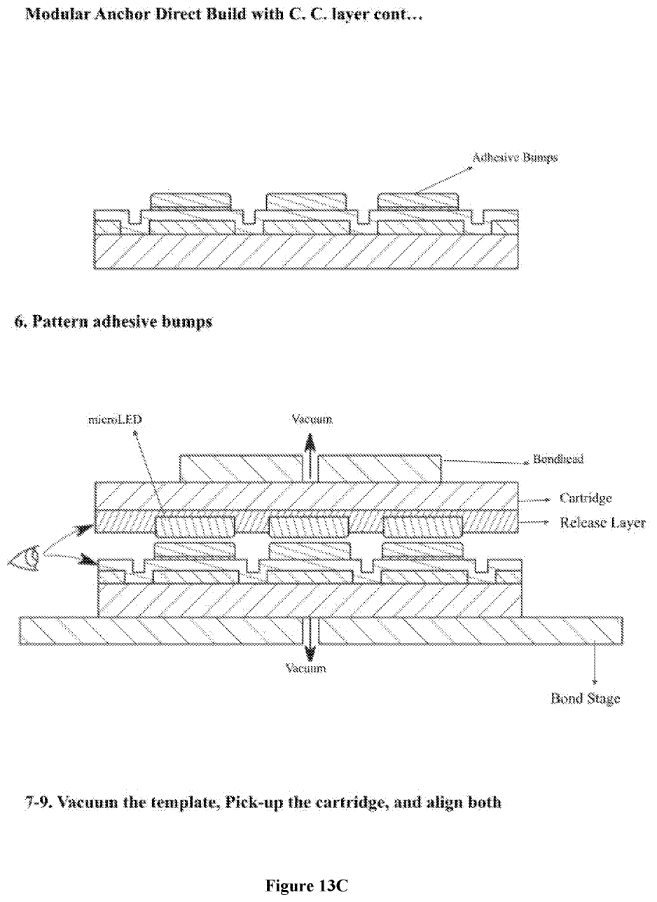

FIGS. 13A, B, and C show a case of a method to build a multi-cartridge.

This implementation involves transfer of microdevices from a cartridge to a release layer located on the template. To facilitate the transfer, a laser-activated release layer is present on the cartridges initially. The backside of the microdevices are bonded to the template's release layer via an adhesive, then the microdevices are released from the cartridge using laser excitation. In this scenario the cartridge would act as a donor substrate while the template is a receiver substrate.

Here the template is with individual bonding pads, where microdevices are bonded to the bonding pads. The microdevices are bonded to the template so the faces connecting to the system substrate are facing away from the template. The microdevice density in the template is higher than the system substrate. The template is multiple of donor substrate used to populate the template with microdevices. The bonding pads can be formed on a diaphragm anchored to the template.

A typical process for this build comprises of:
1. Forming a release layer on the template with opening for anchor points in a diaphragm layer.
2. Forming fiducials to improve the alignment accuracy during microdevice integration to the template.
3. Deposit a diaphragm layer which is anchored to the template substrate, then pattern it to individual diaphragm associated to each microdevice to allow separating individual microdevices from the template during the transfer process.
4. The template substrate may include more than one template piece and so it can be separated into several template pieces by mechanical dicing or laser cutting or other means. This step can be done after microdevice integration into the template.
5. Pattern bonding pads/bumps on top of the diaphragm layer to transfer all microdevices from the cartridge to the template-depending on the microdevice structure, the pads of the microdevice can be facing the diaphragm or facing away from the diaphragm.—the bonding pads can be adhesive polymer, metal layer or other materials. In one related structure the template can only include the bonding pads. The bonding pads can be temporary bonds. The bonding pads can be larger, equal or smaller than the microdevice. In one related case, the bonding pads can be more than multiple times smaller than the microdevice and so multiple of the bonding pads contact one microdevice.
6 Align a donor substrate with secured microdevices facing toward the template bonding pads with a location in the template. The devices can be secured to the donor substrate with different means such as adhesive, mechanical release layers, or other sort. Bond the microdevices of the donor to the template. The bonding may include heat and pressure. The heat and pressure may only be applied to the donor substrate only. The bonding can be carried for all the microdevices in the donor substrate or a selected set of microdevices in the donor substrate.
7. Repeat steps 4-6 until all desired locations on the template are filled, creating a multi-cartridge.
8. The donor substrate can be removed after the bonding process individually or after all bonding. The removing process can be done by mechanical force, laser, heat, or chemical release assistant to leave the microdevices into the template. After or before donor substrates are removed, further curing may be done to further secure the microdevices. The release process may be carried out selectively for a set of microdevices in the donor substrate or for all the microdevices in the donor substrate.
9. The release layer is moved. One method is to etch the sacrificial layer to release free-standing diaphragm which can be used to print microdevices from the multi-cartridge.

To carry the steps associated with transferring microdevices into the template, the template can be secured to a flat stage tool stage so that diaphragm and the adhesive layer are facing away from the stage, and the donor substrate with microdevices secured to it by different means is picked by a flat transfer head so that the microdevices can face the template.

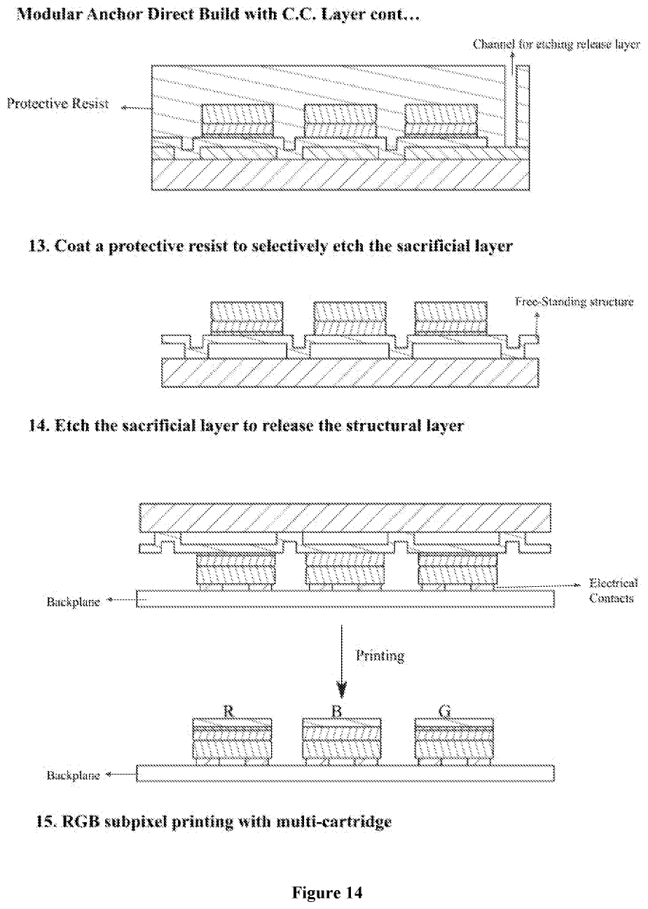

FIG. 14 shows that a tool can be used that has vacuum holes aligned with the cartridges in the carrier substrate. This way we can pick the cartridges without a second adhesive or bonding. Removing the backplane from the cartridge makes the bonding easier.

Modular Anchor Direct Build with Color Conversion

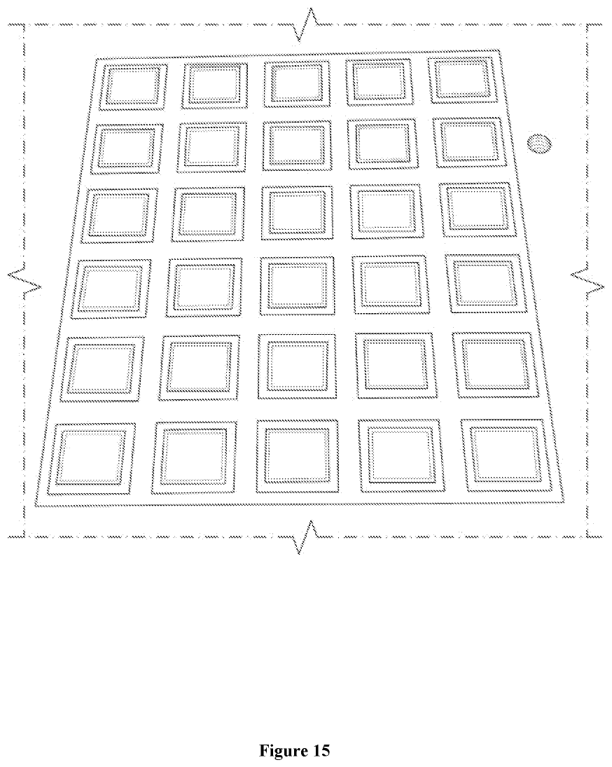

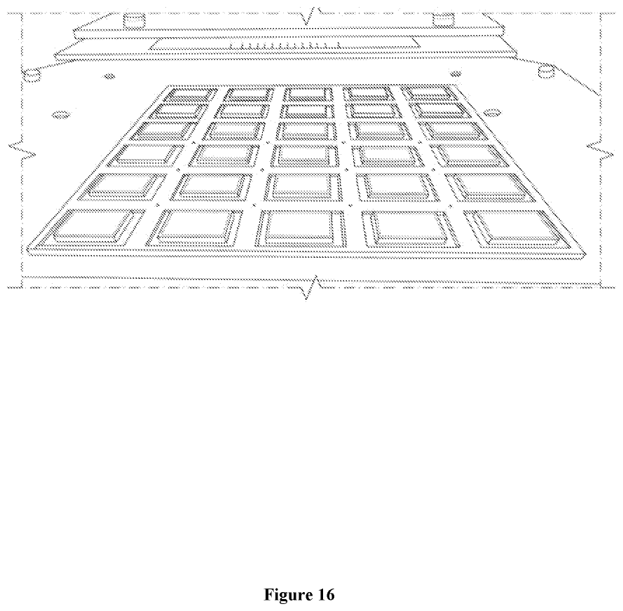

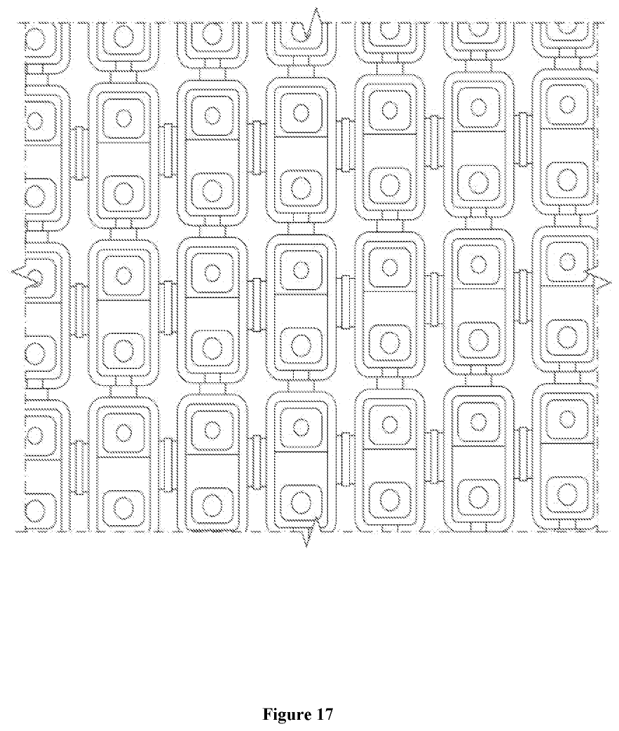

FIGS. 15, 16 and 17 shows that the implementation is identical to implementation Modular Anchor Direct Build, but a color conversion layer is embedded into the structural layer and will be transferred along with the microdevices, specifically microLED's, to allow for RGB color printing directly from the multi-cartridge. This is shown in FIGS. 8, 9, 10 and 11.

A typical process for Modular Anchor Direct Build with Color Conversion would go as follows:
1. Form a release layer on the template with opening for anchor points in a diaphragm layer.
2. Form fiducials to improve the alignment accuracy during microdevice integration to the template.
3. Deposit a diaphragm layer which is anchored to the template substrate, then pattern it to individual diaphragm associated to each microdevice to allow separating individual microdevices from the template during the transfer process.
4. Template substrate may include more than one template piece and so it can be separated into several template pieces by mechanical dicing or laser cutting or other means. This step can be done after microdevice integration into the template.
5. Functional layers such color conversion layers can be integrated on top of diaphragm. The functional layers can include one or more of the one of passivation layers, color conversion layer, color filter and other layers. There can be different types of color conversion layers for different colors.
6 Pattern bonding pads on top of the diaphragm structural layer to transfer microdevices from the donor substrate to the template-depending on the microdevice structure, the pads of the microdevice can be facing the diaphragm or facing away from the diaphragm.—the bonding pads on the template can be adhesive polymer, metal layer or other materials. In one related structure the template can only include the bonding pads. The bonding pads can be temporary bonds. In this case, the functional layers are formed on the template. The bonding pads can be larger, equal or smaller than the microdevice. In one related case, the bonding pads can be more than multiple times smaller than the microdevice and so multiple of the bonding pads contact one microdevice.
7. Microdevices can be integrated into the bonding pads of the template by aligning a donor substrate with the area of the template. bonding a selected set of microdevices into the bonding pads. The process can be repeated till all selected areas of templates are populated with microdevices. The donor substrates can be removed by different means (laser, mechanical force, chemical release or other means) after each individual bonding or at the end.
8. A reflective layer may be formed around the part of the sidewalls of the bonding pads on the template or part of the microdevice sidewalls to direct the input light or out coupling light through the bonding pads.
9. The bonding pads are transparent or translucent to the wavelength generated by the microdevice or the light intended to enter the microdevice.

In another related structure the functional layers are formed on top of the bonding pads. here the bonding pads can have some opening to embed the functional layers. The opening can be formed by lithography, wet etching or dry etching.

The following table outlines various advantages of materials used in combination of structural and sacrificial layers:

| Structural | Sacrificial | | |
|---|---|---|---|
| Layer | Layer | Pros | Cons |
| Silicon | Aluminum | High thermal budget | Corrosive etchant |
| Oxide | | High elastic modulus | release |
| | | structural layer | |
| Silicon | Aluminum | High thermal budget | Corrosive etchant |
| Nitride | | High elastic modulus | release |
| | | structural layer | |
| | | High refractive index | |
| | | (improved light | |
| | | coupling from epoxies) | |
| Poly- | Silicon | High thermal budget | Corrosive etchant |
| silicon | Oxide | Very high elastic | release |
| | | modulus structural | Opaque to visible |
| | | layer | light, must be |
| | | MEMS-foundry | removed after |
| | | compatible | optical microdevice |
| | | | transfer |
| Low-temp | Polycarbon- | Thermal release | Low thermal budget |
| Silicon | ate-based | High throughput | Material |
| Nitride | Polymer | processing | incompatibilities |
| | | | (e.g., Organic |
| | | | solvents) |
| SU8 | Poly(vinyl) | Geometry shaping with | Low thermal budget |
| | alcohol | grayscale lithography | Material |
| | | or structured light | incompatibilities |
| | | Seamless bonding and | (e.g., Organic |
| | | light coupling with | solvents) |
| | | adhesive layers | Viscoelastic |
| | | Very high throughput | structural layer |
| | | processing | |
| SU8 | Polyimide | Geometry shaping with | Low thermal budget |
| | | grayscale lithography | Material |
| | | or structured light | incompatibilities |
| | | Seamless bonding and | (e.g., Organic |
| | | light coupling with | solvents) |
| | | adhesive layers | Viscoelastic |
| | | Very high throughput | structural layer |
| | | processing | |

In another related structure the functional layers are formed on top of the bonding pads. here the bonding pads can have some opening to embed the functional layers. The opening can be formed by lithography, wet etching or dry etching.

### Transfer Head

The following aspects apply to all methods of multi cartridge build as mentioned above where appropriate.

The present invention relates to a transfer head loading multiple cartridges with high alignment precision, simultaneously transferring microdevices from each cartridge into a substrate selectively where the cartridge includes substrate, transfer layers and microdevices coupled to the cartridge substrate through transfer layers.

One method of loading multiple cartridges into a transfer head is to precisely secure the cartridges into a template face down (microdevices facing the template), peaking the cartridges from the back of cartridge substrate with the transfer head.

The transfer heads hold multiple cartridges through adhesive layer, vacuum, electrostatic or other forces.

The present invention also relates to loading a cartridge with microdevices from a donor substrate where the process include forming release layers on a substrate, forming a diaphragm on the release layer where the diaphragm is connected to the substrate through some opening in the release layer, bonding microdevices to the diaphragm through an adhesive or bonding layer.

The diaphragm can be patterned to hold only single microdevices or multiple microdevices.

Removing the release layer reduces the force holding diaphragm to the substrate.

Aligning microdevices in the substrate with a system substrate and bonding microdevices selectively with bonding areas in the system substrate can remove the microdevices from the cartridge substrate. The diaphragm can and bonding layers can be removed after transfer of microdevices into the system substrate. In one case the bonding layer and diaphragm are transparent and so they can stay on the microdevice.

The present invention also relates to a multi-cartridge structure where it includes, a template substrate, a release or sacrificial layer with opening, a diaphragm layer coupled to the substrate through the opening in the release layer, microdevices from different donor substrate are coupled to the diaphragm layer by an adhesive layer on the diaphragm layer, wherein the diaphragm can be patterned to an array of individual diaphragm.

Further, the adhesive layer can be patterned to an array matching microdevices array coupled to the adhesive layer. Functional layers formed on top of diaphragm layers where the functional layers include one or more of passivation, colour conversion, colour filter layers, and optical structure.

The functional layers are patterned into an array of functional layers. Reflective layers around template bonding pads, functional layer or part of the micro devices are used to direct the light through the functional layer.

The release or sacrificial layer can be removed, and the diaphragm layer is free standing. A set of microdevices bonded to free standing diaphragm can be bonded to bonding pads on a system substrate through system substrate bonding pads. The selected set of freestanding diaphragms with the associated microdevices are separated from the template and stay on the system substrate.

The present invention also relates to a method to build a multi-cartridge where the method comprising, forming a release layer on a template with opening for anchor points in a diaphragm layer, forming fiducials to improve the alignment accuracy during microdevice integration to the template, depositing a diaphragm layer which is anchored to the template substrate, patterning bonding pads/bumps on a top of the diaphragm layer.

Further transferring microdevices from at least one donor into an area in the template by Aligning a donor substrate with secured microdevices facing toward the template bonding pads in a location in the template, Bonding the donor substrate to the location in the template, and releasing the microdevices into the template.

The devices are secured to the donor substrate with different means such as adhesive, or mechanical release layers., wherein further the microdevices of the donor are bonded to the template.

In a related embodiment, the diaphragm can be patterned to individual diaphragms associated to each microdevice allowing separating individual microdevices.

In a related embodiment, the pads of the microdevice are facing the diaphragm or facing away from the diaphragm, the bonding pads are adhesive polymer, or metal layer.

In a related embodiment, only the template may include the bonding pads wherein the bonding pads are temporary bonds and are larger, equal or smaller than the microdevice.

In a related embodiment, the bonding pads are more than multiple times smaller than the microdevice and so multiple of the bonding pads contact one microdevice.

In a related embodiment, the donor substrate can be removed after the bonding process individually or after all bonding and the removing process is done by mechanical force, laser, heat, or chemical release assistant to leave the microdevices into the template.

In a related embodiment, a release process is carried out selectively for a set of microdevices in the donor substrate or for all the microdevices in the donor substrate.

In a related embodiment, after or before the donor substrates are removed, further curing is done to further secure the microdevices.

In a related embodiment, the release layer is moved by etching the sacrificial layer to release free-standing diaphragm which are used to print microdevices from the multi-cartridge.

In a related embodiment, functional layers are formed on a top of the diaphragm wherein the functional layers include one or more of the one of passivation layers, color conversion layer, color filter, and optical structure.

In a related embodiment, the donor substrates are removed by laser, mechanical force, or chemical release after each individual bonding or at the end.

In a related embodiment, a reflective layer is formed around a part of the sidewalls of the bonding pads on the template or a part of the microdevice sidewalls to direct an input light or out coupling light through the bonding pads.

In a related embodiment, the bonding pads are transparent or translucent to a wavelength generated by the microdevice or a light intended to enter the microdevice.

In a related embodiment, functional layers are formed on top of the bonding pads, wherein further the bonding pads have an opening to embed the functional layers and the opening is formed by lithography, wet etching or dry etching.

In a related embodiment, the release or sacrificial layer is removed, and the diaphragm is a freestanding structure.

In a related embodiment, microdevices are transferred selectively from the template into a system substrate by selectively aligning a set of microdevices in the template with bonding pads on the system substrate and removing the diaphragm from the template where diaphragm include template bonding pads and microdevices.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

1. A method to build a multi-cartridge, using an adhesive based direct build, the method comprising:
patterning alignment marks on a highly planar substrate and dice the planar substrate into several template pieces;
applying an adhesive to a template;
picking up a cartridge face-up with a bond head;
aligning a back of the cartridge and a top of the template using the alignment marks or cartridge corner present on both surfaces;
bonding the cartridge to the template; and
repeating the last three steps until all desired cartridge locations on the template are filled and a multi-cartridge build is complete.

2. The method of claim 1 wherein the adhesive is thermally cured.

3. The method of claim 1 wherein only the bond head applies a temperature.

4. The method of claim 1 wherein a misalignment is actively corrected by bonding tools.

5. The method of claim 1 wherein there is testing and corner detection of the backside of the cartridge.

6. The method of claim 1, wherein there is a custom recess in a bond-head.

7. A method to build a multi-cartridge, using an adhesive based simultaneous build, the method comprising:
patterning alignment marks on a highly planar substrate;
patterning adhesive bumps on a highly planar temporary bonding substrate to selectively transferring microLED's from a cartridge;
holding the temporary bonding substrate to a tool stage;
picking-up the cartridge face-down using a bond-head;
aligning a top of the cartridge and the adhesive bumps on the substrate using fiducials or other features (ex. cartridge corner) present on both surfaces;
bonding the cartridge to the substrate such; and
repeating steps 4-6 until all desired cartridge locations on the substrate are filled.

8. The method of claim 7 wherein only the bond-head is applying heat in order to prevent adhesive curing of the whole substrate.

9. The method of claim 7 wherein, the method further comprises applying adhesive to the template via spinning, spraying, dipping, or rod coating.

10. The method of claim 9 wherein, the method further comprises picking-up the template face-down using a vacuum bond-head.

11. The method of claim 10 wherein the method further comprises aligning the top of the template and the temporary substrate using fiducials present on both surfaces.

12. The method of claim 11 wherein the method further comprises bonding the template to the backside of all cartridges simultaneously and lift-off from the tool stage.

13. The method of claim 12, wherein removing template causes transferring some microLED's onto the adhesive bumps, to complete the multi-cartridge.

14. The method of claim 1, using an adhesive based build with spacer beads, the method comprising:
augmenting an x-axis alignment and a y-axis alignment by controlling a z-axis depth by maintaining a consistent bond-line thickness across the template adhesive at all cartridge locations by using spacer beads comprising of size-controlled spherical glass or ceramic particles into the adhesive to allow for the bond-line thickness of all cartridges fixed to the template to remain uniform.

15. The method of claim 14, wherein the bond-line thickness is set by the largest beads present underneath each cartridge at the time of bonding.

16. The method of claim 7, using an adhesive based build with spacer beads, the method comprising:
augmenting an x-axis alignment and a y-axis alignment by controlling a z-axis depth by maintaining a consistent bond-line thickness across the template adhesive at all cartridge locations by using spacer beads comprising of size-controlled spherical glass or ceramic particles into the adhesive to allow for the bond-line thickness of all cartridges fixed to the template to remain uniform.

17. The method of claim 16, wherein the bond-line thickness is set by the largest beads present underneath each cartridge at the time of bonding.

18-72. (canceled)
